(19) United States
(12) Patent Application Publication
(10) Pub. No.: US 2015/0069946 A1
(43) Pub. Date: Mar. 12, 2015

(54) ELECTROMOTIVE DRIVE ARRANGEMENT

(71) Applicant: DewertOkin GmbH, Kirchlengern (DE)

(72) Inventors: Karsten Gehrke, Porta Westfalica (DE); Stefan Langejürgen, Vlotho (DE); Steffen Loley, Osnabruck (DE)

(73) Assignee: DewertOkin GmbH, Kirchlengern (DE)

(21) Appl. No.: 14/259,830

(22) Filed: Apr. 23, 2014

Related U.S. Application Data
(63) Continuation of application No. 12/742,821, filed on Sep. 14, 2010, now abandoned.

(30) Foreign Application Priority Data
Nov. 13, 2007 (DE) 10 2007 054 421.0

(51) Int. Cl. H02K 11/00; G01R 31/34

(52) U.S. Cl. CPC H02K 11/001; H02K 11/0094; G01R 31/34
USPC 318/490; 324/765.01

(57) ABSTRACT

An electric-motor drive arrangement is proposed having at least one electric motor and having at least one control device, wherein the electric-motor drive arrangement has a measurement data processing apparatus and a non-volatile memory. In this case, the memory is connected to a comparator which operates at least one optical display block of a display apparatus when a predetermined set value is reached or exceeded.

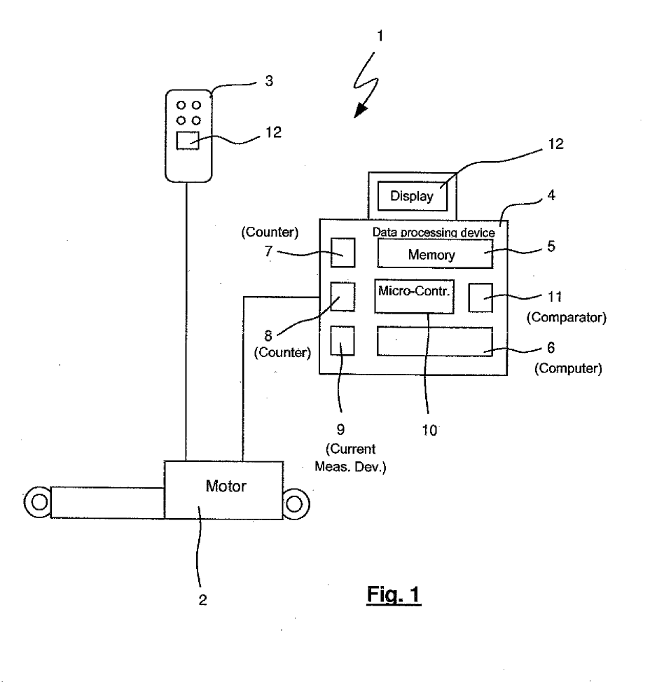

### CROSS-REFERENCES TO RELATED APPLICATIONS

This application is a continuation of prior filed copending U.S. application Ser. No. 12/742,821, filed Sep. 14, 2010, the priority of which is hereby claimed under 35 U.S.C. §120, which in turn is the National Stage of International Application No. PCT/EP2008/065427, filed Nov. 12, 2008, which designated the United States and has been published as International Publication No. WO 2009/062983 and claims the priority of German Patent Application, Serial No. 10 2007 054 421.0, filed Nov. 13, 2007, pursuant to 35 U.S.C. 119(a)-(d), the contents of which are incorporated herein by reference in its entirety as if fully set forth herein.

### BACKGROUND OF THE INVENTION

The invention relates to an electromotive drive arrangement with at least one electric motor and with at least one control device and a method for determining a wear state of this drive arrangement. The electromotive drive arrangement can have a linearly movable or a rotatable driven element which is operatively connected to an adjustable component of an item of furniture, for example in form of a slatted frame or an upholstered chair, or which is operatively connected to an adjustable component of a care product, for example a hospital bed, a nursing bed, a patient lift or a lounger. The electromotive drive arrangement according to the invention can be operated by actuating a foot switch and/or a manual switch, which controls the at least one electric motor either directly or via an interconnected control device.

Such electromotive drive arrangements are known in the art and have proven effective in practical applications. They are encapsulated and maintenance-free. However, they are subject to wear and aging as a result of the use, which limits their useful life. The wear depends on the conditions of use, for example the frequency of use, the switch-on duration, the load factor and the type of the load.

In some applications, the service performance of an electromotive drive arrangement needs to be reviewed. This applies, for example, to the medical field, where after a certain operating time and commensurate with applicable regulations, maintenance work and parts exchange may be required. However, manual records have not proven to be effective in practice, because they are cumbersome and because the effective performance can only be estimated. Likewise, only estimates of the service performance are possible from on the year stamped on the identification plate, which may cause an electromotive drive arrangement to be classified as used up too early, or as being serviced too late.

It is therefore an object of the invention to provide an electromotive drive arrangement without the aforementioned disadvantages, which can be easily installed and which includes a device capable of measuring at least the service performance, i.e., the wear state, of the electromotive drive arrangement and of displaying the same to the user.

The object of the invention is attained with an electromotive drive arrangement having at least one recording device in form of a measurement data processing device with an externally mounted or integrated storage device with a non-volatile memory, as well as a counting device in form of an adder and a comparator, wherein the memory has a stored value which corresponds to the service performance or the wear state of the electromotive drive arrangement. The measurement data processing device is provided for determining this at least one value which corresponds to the wear of the electromotive device, which is stored in the memory, and which is displaced.

According to a conceptually simple embodiment, the corresponding control switch for the respective electric motor is coupled to a measurement data processing device. The measurement data processing device is connected to the output of a switch-on counting device, wherein the measurement data processing device counts the number of switch-on processes and adds those to the value that was previously stored in the non-volatile memory. The corresponding control switch of the respective electric motor can be formed by a switch in a control device. In another embodiment, the control switch can be formed by an electromechanical switch of the control device. The control switch may also be formed by a switch having a switching output terminal that can be triggered by the current flowing through the motor.

According to a modified embodiment, only switch-on processes in a single rotation direction of the electric motor are counted.

According to another embodiment, the measurement data processing device includes a computer program and a timing pulse generator or time measuring device. In this case, a relationship between the number of the switch-on processes and the switch-on duration of the electric motor is inferred in a predefined computing routine, so that the computed result is added in form of a value to the previously stored value of the non-volatile memory.

According to another embodiment, at least one electric quantity, for example in form of the electric current, is measured. To this end, the circuit of the respective electric motor includes a current measuring device, which may include an electric resistance embodied, for example, as a shunt. It has been observed that the characteristic of the current flow is a measure of the mechanical power produced by the electromotive drive arrangement and therefore represents the mechanical wear and the electrical wear. For example, if the motor circuit has a high current flow, then the mechanical power produced by the electromotive drive arrangement is also high. If the measurement data processing device according to another embodiment has additionally a time measuring device and if the motor circuit has a high current flow during a prolonged switch-on time, then the electromotive drive arrangement has a high dissipated mechanical energy.

According to another embodiment, the measurement data processing device includes a different computer program, which is operatively connected with the output of a current measuring device and with a time measuring device. To this end, a microcontroller can be provided, of which at least one input is connected to an electrical resistor, for example a shunt, which is interposed in the motor circuit. In a predetermined computing routine, the output of the current measuring device is connected with the time measuring device, so that the computed result is added in form of a value to the previously stored value of the non-volatile memory.

In a modification of the aforementioned embodiments, the measurement data processing device includes a different computer program, which is connected with the output of a current measuring device, a time measuring device and with the output of a switch-on counter. In this case, a computed value is determined according to a predefined computing routine, which is then added to the previously stored value of the non-volatile memory.

It has been observed that the switch-on duration, the switch-on frequency and the magnitude of the current flow in the corresponding electric motor are a significant representation of the service performance of the electromotive drive arrangement. It has also been observed that, for example, a long switch-on duration at a small current flow has only a small effect on the service performance. Conversely, it has been observed that a high current flow, in particular an excessive current flow due to mechanical overloading of the electromotive drive arrangement, has a significant effect on its service performance. Another significant impact on the service performance of the electromotive drive arrangement can caused by a high switch-on frequency, where the electric motor is only switched off during short intervals.

The measurement data processing device therefore includes a computing routine which takes these properties into consideration and accordingly outputs a large computed value for a large impact on the service performance or a small computed value for a small impact on the service performance, which is then added to the value previously stored in the non-volatile memory. The computing routine can be integrated in the measurement data processing device or can be hardwired into the measurement data processing device. According to another embodiment, the computing routine may be interchangeable. To this end, the measurement data processing device includes terminals which are connected with a programming device via a wired or a wireless transmission path.

In the aforementioned embodiments, the measurement data processing device may include a microcontroller and a non-volatile memory. However, the measurement data processing device may also be connected thereto or formed therewith. According to a preferred embodiment, the measurement data processing device may be implemented as a digital computer, with the non-volatile memory storing the stored value in digital form. According to another embodiment of a measurement data processing device, the measurement data processing device may be implemented similar to an analog computer, for example in form of connected operational amplifiers, with the non-volatile memory including at least one integrator.

The memory is further connected with a comparator which can be part of a measurement data processing device. The comparator compares the actual value stored in the memory with the predetermined nominal values and outputs at its output a switching signal as soon as the actual value has reached or exceeded the nominal value. According to another embodiment, several nominal values are associated with the comparator. The comparator may have at its output several switching outputs and/or switching signals.

In an advantageous embodiment, the electromotive drive arrangement includes a display device which is connected to the comparator and/or the measurement data processing device. According to an advantageous embodiment, the display is implemented as an optical display and can be formed, for example, by an LCD or an LED display. The display may include several display blocks, wherein each display block is connected with a switching output of the comparator and/or the measurement data processing device. The display blocks may be implemented in a single color or in multiple colors.

A predetermined nominal value is associated with each display block. According to this embodiment, the service performance attained by the electromotive drive arrangement can be displayed to the user of the electromotive drive arrangement. When an almost full service performance has been attained, the optical display device can be configured to fluctuate, for example blink. When the maximal allowable service performance is reached or exceeded, a switching output of the measurement data processing device can transmit a switching signal to the control device such that the respective electric motor is switched off or can only be switched on for short periods of time. In a modification of this embodiment, the control device may further include a throttle device which only supplies very little electric energy when the corresponding electric motor is switched on.

According to yet another embodiment, the value stored in the non-volatile memory may be read out by a reading device, for example in form of a laptop or a PC. The value can here be transmitted to the reading device via a wired or a wireless transmission path.

In addition, the memory may have a high capacity, so that at least a portion of the current curve and/or the switch-on duration can be stored therein during the service life of the electromotive drive arrangement. According to another embodiment, the memory includes several stored values representing the maximal current flow and/or its frequency.

According to an embodiment of the computing routine, the computing routine includes a factor in form of an operating time factor, which may be varied within predefined limits. The operating time factor takes into account the past operation of the electromotive drive arrangement and can have a value, for example, between 1 and 1.5. For example, if the electromotive drive arrangement is relatively new, then the operating time factor has a small value, for example, a value of 1. The operating time factor is increased step-wise or continuously according to a table or a computed formula with increased use of the electromotive drive arrangement and can assume a maximum value of 1.5. The table or computed formula is stored in a non-volatile memory. Advantageously, a frequently used electromotive drive arrangement is hereby given more weight by the computing routine than a new drive arrangement.

In a modified embodiment, the magnitude of the operating time factor is coupled to the switch-on counting device in such a way that the operating time factor increases when the number of switch-on processes increases.

In another embodiment, the operating time factor is coupled with the current measuring device, wherein the current measuring device measures the used current in form of an electric meter, and wherein the operating time factor increases with increasing electric meter readings.

In a modification of the aforementioned embodiments, the measurement data processing device includes an additional computer program which is connected with the output of a current measuring device and with the output of a switch-on counting device, and wherein the computing program has a predetermined operating time factor. A computed value is determined according to a predetermined computing routine, wherein the computed value is then added to the previously stored value of the non-volatile memory.

Another embodiment includes a combination of the aforementioned embodiments, wherein at least one operating time factor is coupled to both the switch-on counting device and the current measuring device.

According to another embodiment of the electromotive drive arrangement, at least two non-volatile memories, each having at least one memory section with at least one corresponding predefined stored value, are provided, wherein for example the first non-volatile memory is configured to be reset to an additional previously defined value. The reset can advantageously be performed, for example, manually, whereas the second non-volatile memory can only be changed by the computing routine through addition of values. The second non-volatile memory may include additional values stored in one or several additional memory sections, which were collected during this service life of the drive arrangement, for example, as measurement value data. Such values may be data representative, for example, of the frequency and/or the magnitude of overloading of the electromotive drive arrangement.

As mentioned in detail above, the values stored in the non-volatile memory may be read out by a reading device, for example in form of a laptop or a PC. In an advantageous modification of this embodiment, the reading device may be implemented in form of an adapter which either has or does not have its own power supply. In the embodiment, where the adapter does not have its own current supply, the adapter is powered by the electromotive drive arrangement during the time the adapter is electrically connected to the electromotive drive arrangement. In the same manner, the data residing in the non-volatile memory are transferred to an additional non-volatile memory arranged in the adapter.

The invention will now be described with respect to a preferred embodiment and with reference to the FIGURE of the appended drawing.

### BRIEF DESCRIPTION OF THE DRAWING

The FIGURE shows an electromotive drive arrangement 1 with a motor 2, a control device 3 and a measurement data processing device 4.

### DETAILED DESCRIPTION OF PREFERRED EMBODIMENTS

The motor 2 is equipped with an unillustrated controller and an associated power supply. The control device 3 is connected to the motor 2 or to its controller and has in this example control elements for moving the motor 2 and a display device 12.

The measurement data processing device 4, which is shown here in an enlarged scale, is coupled to the motor 2. The measurement data processing device 4 includes the following: a non-volatile memory 5; a computing device 6; a counter 8, a current measuring device 9; a microcontroller 10; a comparator 11 and a display device 12.

The measurement data processing device 4 is coupled to the motor 2 in such a way that the operating parameters of the motor 2 are transmitted to the data processing device 4, in this case via hardwired electrical lines.

Each actuation of the control device 3 is accompanied by a switch-on process of the motor 2. These switch-on processes are counted with the counter 7 and summed. At the same time, the time measuring device 8 measures the duration of each switch-on process of the motor 2. When the motor is running, the current through the motor 2 is measured by the current measuring device 9.

The three operating parameters measured and processed in this way, namely the switch-on frequency, the switch-on duration and the current value, are used as input variables for a computing algorithm which is executed by the microcontroller, for example as a program. A corresponding actual value is computed with the computing algorithm from these actual values and compared in the comparator 11 with a stored, previously defined nominal value. Based on this comparison, a wear state is determined and stored as a value in the memory 5. This wear state value is displayed on the display device 12 and visible to the user in a certain form, for example as a graphic illustration, numerical value and/or a colored symbol. This value can also be read from the memory 5, for example with a service device.

Additional values, for example the nominal value or nominal values, can also be stored in the memory 5 in tabular form. Additionally, the operating parameters can be recorded in the function of time, at least during a limited time.

The invention is not limited to the aforedescribed example.

For example, only a single operating parameter or more than the three aforementioned operating parameters may be used.

The memory 5 may also include empirical values in tabular form, indicating a remaining operating time until the next scheduled maintenance.

In a simplified embodiment, a single operating parameter, for example the switch-on frequency, can be summed and use as a value for the wear state.

According to another exemplary embodiment, a tabular value corresponding to the wear state may be determined based on one or several operating parameters. The associated tabular values may be stored, for example, in the memory 5.

What is claimed is:

1. An electromotive drive arrangement for an adjustable component of an item of furniture, the drive arrangement comprising:
at least one electric motor;
a linearly movable or rotatable driven element driven by the electric motor and operatively connected to the adjustable component of the item of furniture;
at least one control device controlling operation of the electric motor;
at least one measurement data processing device comprising a computing device for computing from input values representing operating parameters of the electromotive drive arrangement at least one value that corresponds to wear of the electromotive drive arrangement, wherein the operating parameters comprise all of a number of counted switch-on operations, measured switch-on times and a value of an electric current of the electromotive drive arrangement, and
a memory arranged on or integrated in the measurement data processing device, said memory storing the at least one value corresponding to wear of the electromotive drive arrangement.

2. The electromotive drive arrangement of claim 1, wherein the measurement data processing device further comprises at least one of a counter for counting the switch-on processes of the electromotive drive arrangement or a time measuring device for measuring the switch-on durations of the electromotive drive arrangement, wherein the operating parameters include the counted switch-on processes or the measured switch-on durations.

3. The electromotive drive arrangement of claim 1, wherein the measurement data processing device further comprises a current measuring device for measuring the value of the electric current of the electromotive drive arrangement, said current value representing an operating parameter.

4. The electromotive drive arrangement of claim 1, wherein the measurement data processing device comprises a digital microcontroller or a network of interconnected operational amplifiers in form of an analog computer with at least one integrator, or both.

5. The electromotive drive arrangement of claim 1, wherein the measurement data processing device comprises a comparator for comparing the value corresponding to wear of the electromotive drive arrangement stored in the memory with a predetermined nominal value.

6. The electromotive drive arrangement of claim 5, wherein at least one of the measurement data processing device or the control device comprises a display device configured to display an actual wear state as a function of a comparison value determined by the comparator.

7. The electromotive drive arrangement of claim 6, wherein the display device is constructed as an LCD or an LED display.

8. The electromotive drive arrangement of claim 6, wherein the display device displays the actual wear state of the electromotive drive arrangement in a single color or in multiple colors.

9. The electromotive drive arrangement of claim 6, wherein the display device displays a remaining time until a next scheduled maintenance.

10. The electromotive drive arrangement of claim 1, wherein the memory is read by a reading device.

11. The electromotive drive arrangement of claim 1, wherein the memory is configured for storing at least a segment of a current curve or a switch-on duration of the electromotive drive arrangement, or both.

12. A method for determining an actual wear state of an electromotive drive arrangement having a linearly movable or rotatable driven member, which is operatively connected with a component of an item of furniture to be adjusted, comprising the steps of:
measuring operating parameters of the electromotive drive arrangement, the operating parameters comprising all of a number of counted switch-on operations, measured switch-on times and a value of an electric current of the electromotive drive arrangement;
inputting the operating parameters as input variables in a measurement data processing device for determining a value; and
determining the wear state of the electromotive drive arrangement based on the determined value.

13. The method of claim 12, characterized in that the value is determined from the inputted operating parameters based on stored table values.

14. The method of claim 12, wherein the measurement data processing device determines the value by computation using a predetermined computing algorithm.

15. The method of claim 12, wherein the wear state of the electromotive drive arrangement is determined based on a comparison between the determined value and a predetermined nominal value.

16. The method of claim 15, wherein the wear state obtained based on the comparison is stored in the memory.

17. The method of claim 16, wherein the wear state is displayed on a display device or read from the memory with a suitable reading device.
